(19) United States
(12) Patent Application Publication
(10) Pub. No.: US 2025/0007480 A1
(43) Pub. Date: Jan. 2, 2025

(54) RADIO FREQUENCY (RF) VARIABLE GAIN AMPLIFIER (VGA) WITH VARYING GAIN ELEMENTS

(71) Applicant: QUALCOMM Incorporated, San Diego, CA (US)

(72) Inventors: Chuan WANG, San Diego, CA (US); Li LIU, San Diego, CA (US); Vinod PANIKKATH, San Diego, CA (US); Wu-Hsin CHEN, San Diego, CA (US); Yunfei FENG, San Diego, CA (US); Anosh DAVIERWALLA, San Diego, CA (US); Muhammad HASSAN, San Diego, CA (US)

(21) Appl. No.: 18/611,657

(22) Filed: Mar. 20, 2024

Related U.S. Application Data
(60) Provisional application No. 63/511,630, filed on Jun. 30, 2023.

(51) Int. Cl. H03G 3/30; H03F 3/24

(52) U.S. Cl. CPC H03G 3/3042; H03F 3/245; H03F 2200/451; H03G 2201/103; H03G 2201/307

(57) ABSTRACT

Aspects include amplifiers with different units for improved performance. One amplifier has a first transistor with first gate is coupled to a control input, and a first drain is coupled to a first terminal of an output, a second transistor with a second gate is coupled to the control input, and a second drain is coupled to a second terminal of the output. The amplifier has a third transistor with a third drain coupled to the first transistor source, and a third gate is coupled to a first terminal of an input, and a fourth transistor with a fourth drain is coupled to the second transistor source, and a fourth source gate is coupled to a second terminal of the input, where the first transistor source is not connected to the second transistor drain via one or more transistors.

### PRIORITY CLAIM

This application claims the benefit of U.S. Provisional Application No. 63/511,630, filed on Jun. 30, 2023, which is hereby incorporated by reference, in its entirety and for all purposes.

### FIELD

The present disclosure relates generally to electronics and wireless communications. For example, aspects of the present disclosure relate to large phased array systems and routing used to provide signals to circuitry for large phased array antenna systems.

### BACKGROUND

Wireless communication devices and technologies are becoming ever more prevalent. Wireless communication devices generally transmit and receive communication signals. A communication signal is typically processed by a variety of different components and circuits. In some modern communication systems, phased array antennas are used to improve system operation with improved link budgets, system capacity, beamforming, multiple-in multiple-out (MIMO) communications, and other such system operation. Supporting such systems can involve complex system design choices, and managing complex interactions among device elements and signals.

### SUMMARY

Disclosed are systems, apparatuses, and devices comprising or including radio frequency (RF) variable gain amplifiers (VGAs) with varying gain elements.

According to at least one example, a radio frequency (RF) variable gain amplifier (VGA) is provided. The VGA includes: a first transistor comprising a first gate, a first source, and a first drain, wherein the first gate is coupled to a control input, and wherein the first drain is coupled to a first terminal of an output; a second transistor comprising a second gate, a second source, and a second drain, wherein the second gate is coupled to the control input, and wherein the second drain is coupled to a second terminal of the output; a third transistor comprising a third gate, a third source, and a third drain, wherein the third drain is coupled to the first source, and wherein the third gate is coupled to a first terminal of an input; and a fourth transistor comprising a fourth gate, a fourth source, and a fourth drain, wherein the fourth drain is coupled to the second source, and wherein the fourth gate is coupled to a second terminal of the input; wherein the first source is not connected to the second drain via one or more transistors, and wherein the second source is not connected to the second drain via one or more transistors.

According to at least one other example, a wireless communication apparatus is provided. The wireless communication apparatus includes: a phased array transmission circuit comprising a plurality of split signal paths, wherein a first path of the plurality of split signal paths comprises a first radio frequency (RF) variable gain amplifier (VGA), the first RFVGA comprising: a first transistor comprising a first gate, a first source, and a first drain, wherein the first gate is coupled to a control input, and wherein the first drain is coupled to a first terminal of an output; a second transistor comprising a second gate, a second source, and a second drain, wherein the second gate is coupled to the control input, and wherein the second drain is coupled to a second terminal of the output; a third transistor comprising a third gate, a third source, and a third drain, wherein the third drain is coupled to the first source, and wherein the third gate is coupled to a first terminal of an input; and a fourth transistor comprising a fourth gate, a fourth source, and a fourth drain, wherein the fourth drain is coupled to the second source, and wherein the fourth gate is coupled to a second terminal of the input; wherein the first source is not connected to the second drain via one or more transistors, and wherein the second source is not connected to the second drain via one or more transistors.

According to at least one other example, a radio frequency (RF) variable gain amplifier (VGA) is provided that includes an RFVGA unit in a folded configuration. The RFVGA unit includes: a first transistor comprising a first gate, a first source, and a first drain, wherein the first gate is coupled to a control input, wherein the first source is coupled to a first terminal of an output, and wherein the first drain is coupled to a voltage source via a first resistive element; a second transistor comprising a second gate, a second source, and a second drain, wherein the second gate is coupled to the control input, wherein the second source is coupled to a second terminal of the output and wherein the first drain is coupled to the voltage source via a second resistive element; a third transistor comprising a third gate, a third source, and a third drain, wherein the third drain is coupled to the first drain, and wherein the third gate is coupled to a first terminal of an input; and a fourth transistor comprising a fourth gate, a fourth source, and a fourth drain, wherein the fourth drain is coupled to the second drain, and wherein the fourth gate is coupled to a second terminal of the input.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless communication system communicating with a wireless device that can be implemented according to aspects described herein.

FIG. 2A is a block diagram showing portions of a wireless device in which aspects of the present disclosure may be implemented.

FIG. 2B is a block diagram showing portions of a wireless device in which aspects of the present disclosure may be implemented.

FIG. 3A is a block diagram illustrating aspects of a phased array in which aspects of the present disclosure may be implemented.

FIG. 3B is a block diagram illustrating aspects of a phased array in which aspects of the present disclosure may be implemented.

FIG. 4A is a diagram illustrating aspects of a phased array in which aspects of the present disclosure may be implemented.

FIG. 4B is a diagram illustrating aspects of a phased array in which aspects of the present disclosure may be implemented.

FIG. 5A is a diagram illustrating aspects of a radio frequency (RF) variable gain amplifier (VGA) in accordance with aspects of the present disclosure.

FIG. 5B is a diagram illustrating aspects of an RFVGA in accordance with aspects of the present disclosure.

FIG. 5C is a diagram illustrating aspects of an RFVGA in accordance with aspects of the present disclosure.

FIG. 6 is a diagram illustrating aspects of an RFVGA in accordance with aspects of the present disclosure.

FIG. 7 is a diagram illustrating aspects of an RFVGA in accordance with aspects of the present disclosure.

FIG. 8 is a diagram illustrating aspects of an RFVGA in accordance with aspects of the present disclosure.

FIGS. 9A-C are diagrams illustrating aspects of RFVGA including units or branches in a “folded” configuration in accordance with aspects of the present disclosure.

FIG. 10 is a chart illustrating performance aspects of elements of the RFVGA circuitry of FIGS. 5A-5C in accordance with aspects of the present disclosure.

FIG. 11 is a functional block diagram of an apparatus including RFVGAs in a phased array in accordance with some aspects of the present disclosure.

### DETAILED DESCRIPTION

The detailed description set forth below in connection with the appended drawings is intended as a description of exemplary implementations and is not intended to represent the only implementations in which the invention may be practiced. The term “exemplary” used herein means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

The progression of wireless communication infrastructure, particularly for Third Generation Partnership Project (3GPP) fifth generation (5G) millimeter wavelength (mmW) systems, involves the use of antenna arrays with tens, hundreds, or thousands of elements. For example, a 5G New Radio (NR) communication device may support multiple transmitters, multiple receivers and be capable of communication on multiple communication bands. In some examples, the communication device may also include carrier aggregation (CA) where it may simultaneously communicate on multiple communication bands. At millimeter wave frequencies (mmW), power consumption for low area operation is an important area for improved operational performance and user experience. Aspects described herein include systems with a transmission routing structure. Such systems can use enhanced radio frequency (RF) variable gain amplifiers (VGAs) with reduced parasitics that can improve device performance and enable a simplified structure in the fanout of a phased array transmission path.

The split signal paths in a phased array can result in long transmission line with increasing parasitics as additional phased array elements are included (e.g., 8, 64, 128, 1024, etc.) Aspects described herein include a phase immune radio frequency (RF) variable gain amplifier (VGA) in a signal path with reduced parasitics, which can provide large gain control dynamic range and maintain phase performance across the whole dynamic range within specifications in the context of long driven RF transmission lines in a transmission system fanout of a phased array.

Such performance can be used to improve 5G user equipment or terminals (UE), customer premises equipment (CPE), 5G radio area network small cells (FSM), and 5G radio area network base stations (CSM). Further details regarding aspects of the disclosure will be described with respect to the figures.

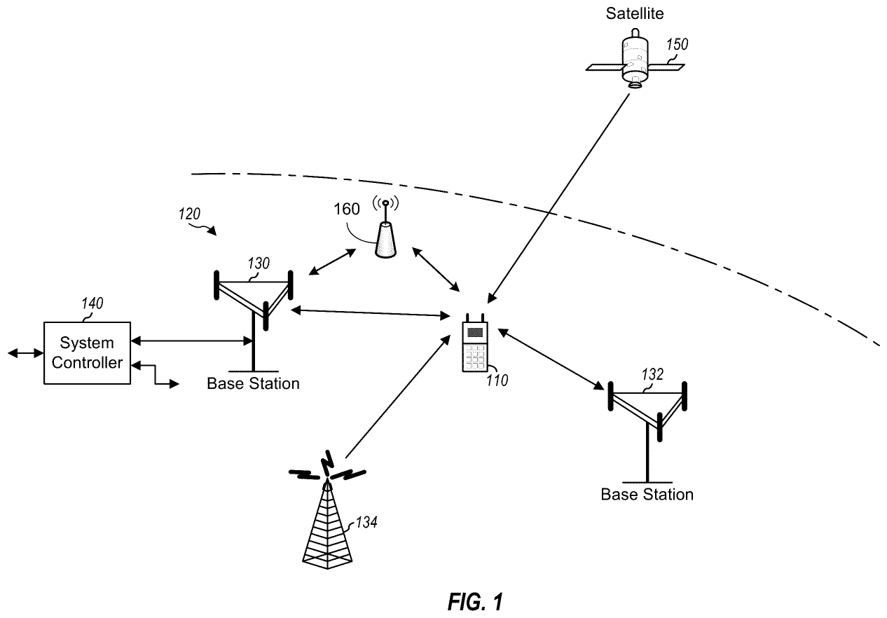

FIG. 1 is a diagram showing a wireless device 110 communicating with a wireless communication system 120. In accordance with aspects described herein, the wireless device can include phased array systems in accordance with aspects described herein. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. Communication elements of the wireless device 110 for implementing mmW and non-mmW communications in accordance with any such communication standards can be supported by various designs of devices including transmission paths in a phased array. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, or other such mobile device (e.g., a device integrated with a display screen). Other examples of the wireless device 110 include a wireless modem, a personal digital assistant (PDA), a handheld device, a laptop computer, a smartbook, a netbook, a tablet, a cordless phone, a medical device, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or signals from satellites (e.g., a satellite 150 in one or more global navigation satellite systems (GNSS), etc.). Wireless device 110 may support one or more radio technologies for wireless communication such as LTE, WCDMA, CDMA 1X, EVDO, TD-SCDMA, GSM, 802.11, 5G, etc.

The wireless communication system 120 may also include a wireless device 160. In an exemplary embodiment, the wireless device 160 may be a wireless access point, or another wireless communication device that comprises, or comprises part of a wireless local area network (WLAN). In an exemplary embodiment, the wireless device 110 may be configured as a customer premises equipment (CPE), which may be in communication with a base station 130 and another wireless device 110, or other devices in the wireless communication system 120. In some embodiments, the CPE may be configured to communicate with the wireless device 160 using WLAN signaling and to interface with the base station 130 based on such communication instead of the wireless device 160 directly communicating with the base station 130. In exemplary embodiments where the wireless device 160 is configured to communicate using WLAN signaling, a WLAN signal may include WiFi, or other communication signals.

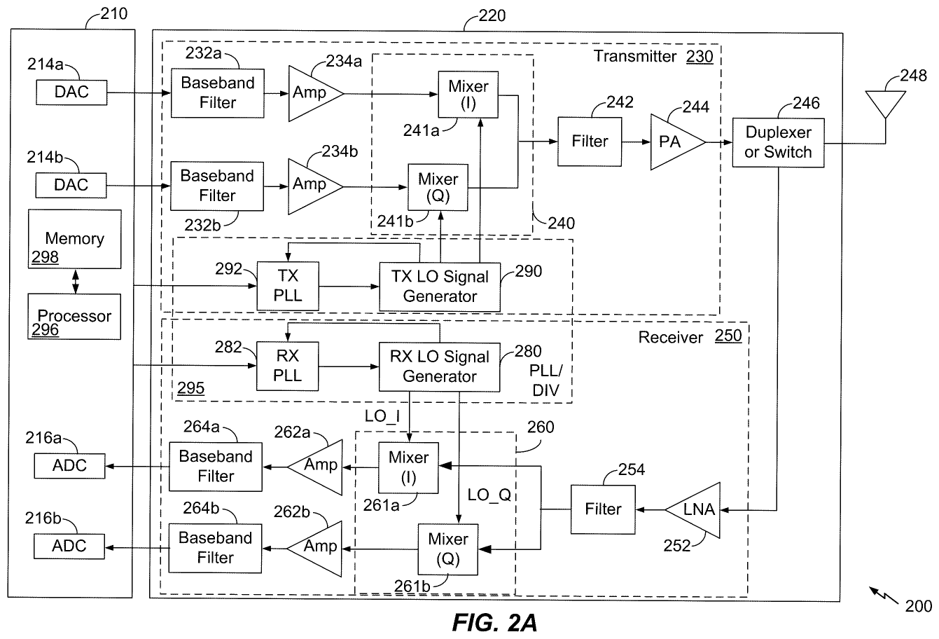

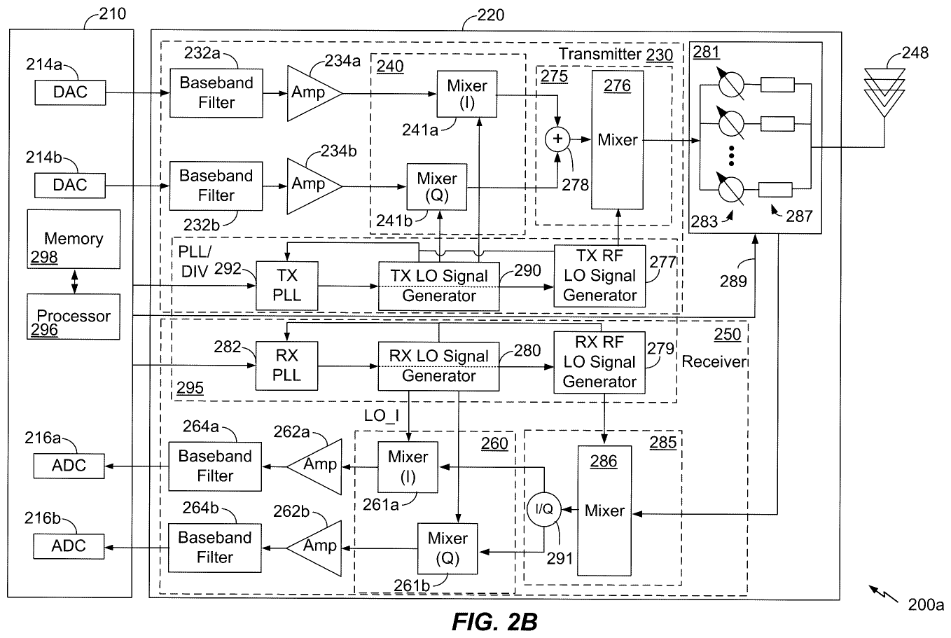

FIG. 2A is a block diagram showing a wireless device 200 in which aspects of the present disclosure may be implemented. The wireless device 200 may, for example, be an embodiment of the devices (e.g., the base station 130 or 132, the wireless device 110 or 160, etc.) illustrated in FIG. 1. The circuitry described may be circuitry supporting mmW communications or other such communications using large arrays of antenna elements structured to transmit signals via fanout paths of phased array systems.

FIG. 2A shows an example of a transceiver 220 including a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250. Unless otherwise noted, any signal in FIG. 2A, or any other figure in the drawings, may be either single-ended or differential. Some circuit blocks in FIG. 2A may also be omitted.

In the example shown in FIG. 2A, wireless device 200 generally comprises the transceiver 220 and a data processor 210. The data processor 210 may include a processor 296 operatively coupled to a memory 298. The memory 298 may be configured to store data and program codes, and may generally comprise analog and/or digital processing components. The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment. the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, baseband (e.g., lowpass) filters 232a and 232b filter the I and Q analog transmit signals, respectively, to remove undesired images caused by the prior digital-to-analog conversion. Amplifiers (Amp) 234a and 234b amplify the signals from the baseband filters 232a and 232b, respectively, and provide I and Q baseband signals. An upconverter 240 including upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier 244 amplifies the signal from filter 242 to obtain the desired output power level and provides a transmit RF signal. The transmit RF signal is routed through a duplexer or switch 246 and transmitted via an antenna 248. While examples discussed herein utilize I and Q signals, those of skill in the art will understand that components of the transceiver may be configured to utilize polar modulation.

In the receive path, the antenna 248 receives communication signals and provides a received RF signal, which is routed through duplexer or switch 246 and provided to a low noise amplifier (LNA) 252. The switch 246 is designed to operate with a specific RX-to-TX duplexer frequency separation, such that RX signals are isolated from TX signals. The received RF signal is amplified by LNA 252 and filtered by a filter 254 to obtain a desired RF input signal. Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by baseband (e.g., lowpass) filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

In an exemplary embodiment, the RX PLL 282, the TX PLL 292, the RX LO signal generator 280, and the TX LO signal generator 290 may alternatively be combined into a single LO generator circuit 295, which may include common or shared LO signal generator circuitry to provide the TX LO signals and the RX LO signals. Alternatively, separate LO generator circuits may be used to generate the TX LO signals and the RX LO signals.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) including various modules, chips, and/or components. For example, the power amplifier 244, the filter 242, and the switch 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the power amplifier 244, and the LNA 252 (and filter 242 and/or 254 in some examples) may be implemented separately from other components in the transmitter 230 and receiver 250, and may be implemented on a millimeter wave integrated circuit. An example super-heterodyne architecture is illustrated in FIG. 2B.

FIG. 2B is a block diagram showing a wireless device in which aspects of the present disclosure may be implemented. Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or superheterodyne) architecture in which the upconverter 240 and the downconverter 260 are configured to process a communication signal between baseband and an intermediate frequency (IF). For example, the upconverter 240 may be configured to provide an IF signal to an upconverter 275. In an exemplary embodiment, the upconverter 275 may comprise summing function 278 and upconversion mixer 276. The summing function 278 combines the I and the Q outputs of the upconverter 240 and provides a non-quadrature signal to the mixer 276. The non-quadrature signal may be single ended or differential. The mixer 276 is configured to receive the IF signal from the upconverter 240 and TX RF LO signals from a TX RF LO signal generator 277, and provide an upconverted mmW signal to phase shift circuitry 281. While PLL 292 is illustrated in FIG. 2B as being shared by the signal generators 290, 277, a respective PLL for each signal generator may be implemented.

In an exemplary embodiment, components in the phase shift circuitry 281 may comprise one or more adjustable or variable phased array elements, and may receive one or more control signals from the data processor 210 over connection 289 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287.

Each phase shifter 283 may be configured to receive the mmW transmit signal from the upconverter 275, alter the phase by an amount, and provide the mmW signal to a respective phased array element 287. Each phased array element 287 may comprise transmit and/or receive circuitry including one or more filters, amplifiers, driver amplifiers, and power amplifiers. In some embodiments, the phase shifters 283 may be incorporated within respective phased array elements 287.

The output of the phase shift circuitry 281 is provided to antennas 248. In an exemplary embodiment, the antennas 248 comprises a number of antennas that typically correspond to the number of phase shifters 283 and phased array elements 287, for example such that each antenna element is coupled to a respective transmit phase shifter and/or a respective receive phase shifter in a phased array element 287. In an exemplary embodiment, the phase shift circuitry 281 and the antennas 248 may be referred to as a phased array.

In a receive direction, an output of the phase shift circuitry 281 is provided to a downconverter 285. In an exemplary embodiment, the downconverter 285 may comprise an I/Q generation function 291 and a downconversion mixer 286. In an exemplary embodiment, the mixer 286 down converts the receive mmW signal provided by the phase shift circuitry 281 to an IF signal according to RX mmW LO signals provided by an RX mmW LO signal generator 279. The I/Q generation function 291 receives the IF signal from the mixer 286 and generates I and Q signals for the downconverter 260, which down converts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC. In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC coupled to the IC including the mixers 276, 286). In some embodiments, the LO signal generators 277, 279 are included in the common IC. In some embodiments in which phase shift circuitry is implemented on a common IC with 276, 286. 277, 278, 279, and/or 291, the common IC and the antennas 248 are included in a module, which may be coupled to other components of the transceiver 220 via a connector. In some embodiments, the phase shift circuitry 281, for example, a chip on which the phase shift circuitry 281 is implemented, is coupled to the antennas 248 by an interconnect. For example, components of the antennas 248 may be implemented on a substrate and coupled to an integrated circuit implementing the phase shift circuitry 281 via a flexible printed circuit board or other such substrate.

In some embodiments, both the architecture illustrated in FIG. 2A and the architecture illustrated in FIG. 2B are implemented in the same device. For example, a wireless device 110 or 200 may be configured to communicate with signals having a frequency below about 20 GHZ using the architecture illustrated in FIG. 2A and to communicate with signals having a frequency above about 20 GHz using the architecture illustrated in FIG. 2B. In devices in which both architectures are implemented, one or more components of FIGS. 2A and 2B that are identically numbered may be shared between the two architectures. For example, both signals that have been downconverted directly to baseband from mmW and signals that have been downconverted from mmW to baseband via an IF stage may be filtered by the same baseband filter 264a, 264b. In other embodiments, a first version of the filter 264a, 264b is included in the portion of the device which implements the architecture of FIG. 2A and a second version of the filter 264a, 264b is included in the portion of the device which implements the architecture of FIG. 2B. As described above, in various aspects in accordance with the disclosures herein, wireless devices can be configured with or without the use of an intermediate frequency (IF).

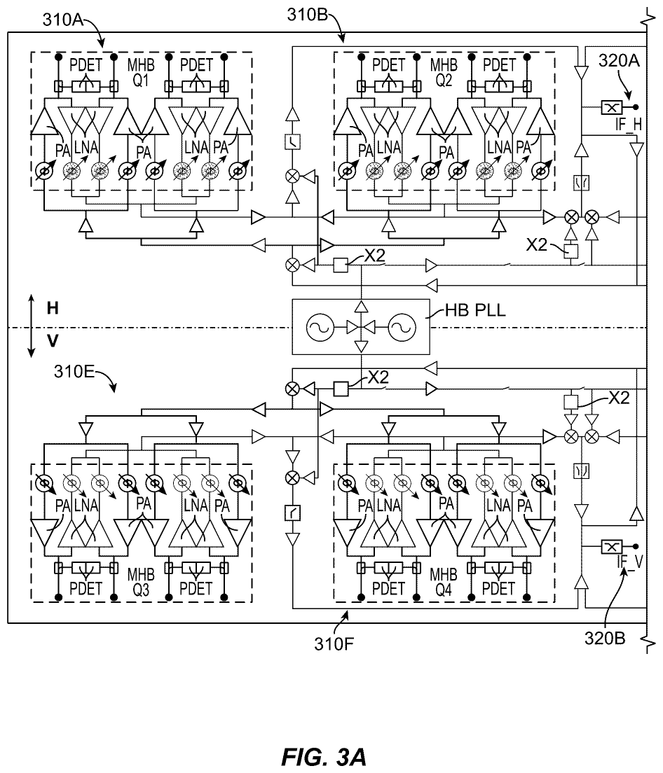

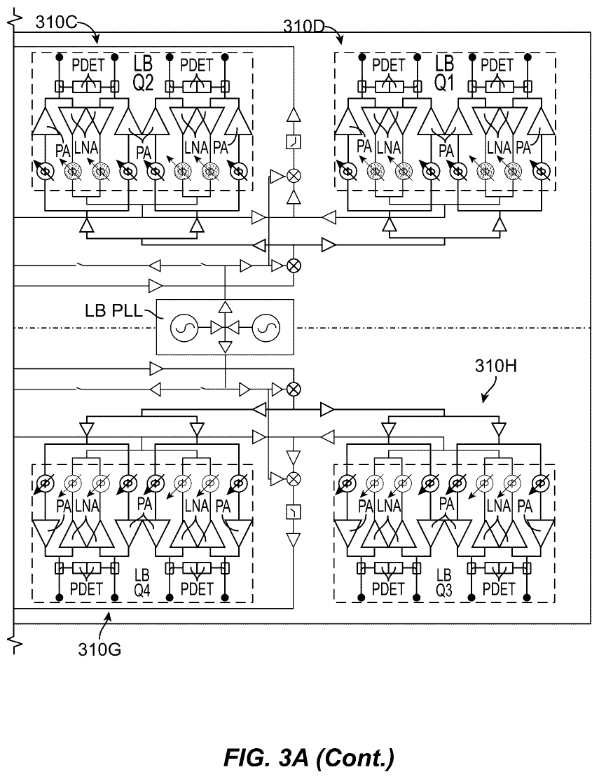

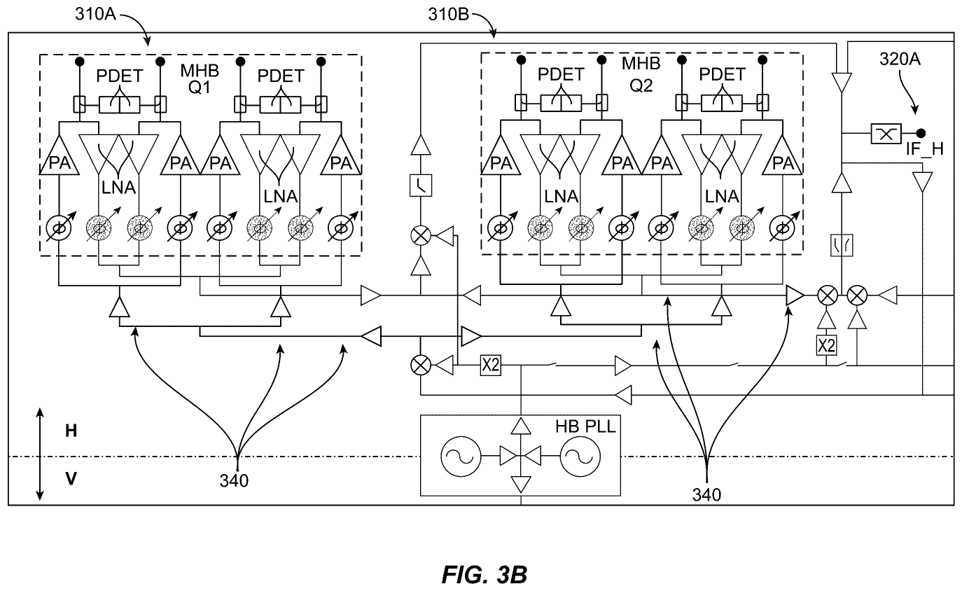

FIG. 3A shows a schematic diagram of a phased array system in accordance with aspects described herein. The system of FIG. 3A includes 8 phased array element structures 310A, 310B, 310C, 310D, 310E, 310F, 310G, and 310H to cover different transmission signals (e.g., polarization, etc.) and different bands within the same hardware. In other implementations, increased or reduced number of phased array element structures can be configured for any number of transmission bands and/or transmission types, (e.g., 16, 32, 64, 256, 1024, etc.). The boxes drawn around phased array element structures 310A, 310B, 310C, 310D, 310E, 310F, 310G, and 310H in FIG. 3A are for illustrative purposes only to aid in the description and understanding of these elements, and do not convey a structural limitation. The system of FIG. 3A may be an example of the phase shift circuitry 281 in combination with the mixers 276, 286 and the LO signal generators 277, 279. In some examples, the system illustrated in FIG. 3A is implemented on a single integrated circuit. One example layout is configured in quadrants, with each quadrant being a combination of a respective polarization and band (e.g., two bands and two polarizations covering the four quadrants). Other layouts are possible. Input/output of the chip to other processing circuitry is through the IF ports 320A, 320B. In the illustrated implementation of FIG. 3A, IF port 320A provides a horizontally polarized signal path to support phased array element structures 310A-D covering horizontally polarized signals, and IF port 320B provides a vertically polarized signal path to support phased array element structures 310E-H covering vertically polarized signals. In other aspects, input and output connections (I/O) can be at baseband frequencies instead of IF frequencies. In some aspects, I/O can connect an RF integrated circuit (IC) implementing the circuitry of FIG. 3A to an IFIC. In other aspects, an RFIC can include I/O directly to an IC operating at baseband frequencies. In some examples, a transmit mixer is coupled to signal paths for multiple antennas. (e.g., in a fanout configuration with successive divisions of the signal path.) In some examples, a single mixer is coupled to each phased array element (287) in a quadrant, for example to each antenna associated with that quadrant. Fanouts and/or long routing associated with having a fanout or mixer coupled to multiple antennas may be associated with certain technical difficulties, as described in greater detail below.

FIG. 3B shows one quadrant of the phased array system of FIG. 3A, including two of the phased array element structures, shown as phased array element structures 310A and 310B, the horizontal IF port 320A, and supporting circuitry 340 of the transmit and receive path fanouts (e.g., amplifiers, transmission lines, etc.). The phased array element structures of FIGS. 3A and 3B may be examples of any number of phased array element structures that may be located in a phased array circuit, such as the phase shift circuitry 281 (FIG. 2B). The phased array element structure may comprise a number of phased array elements (287), each including transmit and/or receive capability. In some aspects, an example receive phased array element may comprise receive circuitry including a low noise amplifier (LNA) and a phase shifter. In some aspects, a fanout routing structure can be used to connect each phased array element to subsequent processing circuitry.

Each LNA may be connected to a port. In a receive application, the port may comprise one or more outputs of an antenna or an antenna element. The antenna element may be one antenna element of a phased array of antenna elements. An antenna system in a phased array may have one or more antennas and one or more antenna elements and may have one or more outputs. An example of outputs from an antenna or an antenna element may be a vertical polarization (V pol) output and a horizontal polarization (H pol) output. In an exemplary embodiment, the routing structure may be configured to provide signals from two of the phase shifters or all of the phase shifters in a given grouping to subsequent processing circuitry, such as, for example, frequency conversion circuitry that may be configured to convert the radio frequency (RF) signals to a lower frequency, such as an intermediate frequency (IF) or baseband, and/or circuitry to combine multiple signals being output from the phase shifters (for example before being provided to an IF port). In other examples, certain received signals are routed together as a combined signal selectively provided to the subsequent processing circuitry, such as frequency conversion circuitry. For example, the frequency conversion circuitry may be configured to convert a signal at 24 GHz or 39 GHz at the port to a frequency of, for example, 10 GHZ. Other frequencies are possible.

In some aspects, phased array elements can be grouped, with phased array elements in one group (e.g., the right side) generally configured to process a signal in a particular band, such as low band, and the phased array elements in another group (e.g., on the left hand side) generally configured to process a signal in a particular band, such as a high band. The terms “high” and “low” as used herein are relative. For example, a low band signal may have a frequency of approximately 24 GHZ and a high band signal may have a frequency of approximately 42 GHZ. Other frequencies are possible, such as a low band frequency of 26 GHZ and a high band frequency of 39 GHz. The provided frequencies are examples only, and other frequencies can be used in other examples. Additionally, further groupings can be created based on signal polarization. For example, the upper phased array elements of FIGS. 3A may be configured to process a horizontal polarization (H pol) signal from respective antennas and the lower phased array elements may be configured to process a vertical polarization (V pol) signal from the respective antennas; however, this convention is one example of a number of different possible configurations.

Similarly, as illustrated in FIGS. 3A and 3B, supporting circuitry 340 includes transmit routing structures and receive routing structures. In the illustrated transmit routing structures, a LO signal from a PLL is provided to a mixer along with an IF or baseband transmit signal to upconvert the transmit signal to an RF frequency for transmission via IF ports 320A, B. Depending on the particular implementation, different mixers can be used in different portions of the RF routing structure to support different frequencies and/or polarizations in different portions of the phased array system. The RF signal is then transmitted via a transmission line fanout to each phased array element of the quadrant of the phased array system. At each intermediate path of the transmission line fanout, RFVGAs are present. At a final output path of the transmission line fanout, the RF signal is provided to phase shift circuitry and power amplifier (PA) circuitry which is switchably connected (e.g., with switches to select between transmit and receive portions of the phased array circuitry) to an antenna element. While the term “transmission line” is used herein, it will be understood that other forms of routing, traces, conductors, etc. may be used.

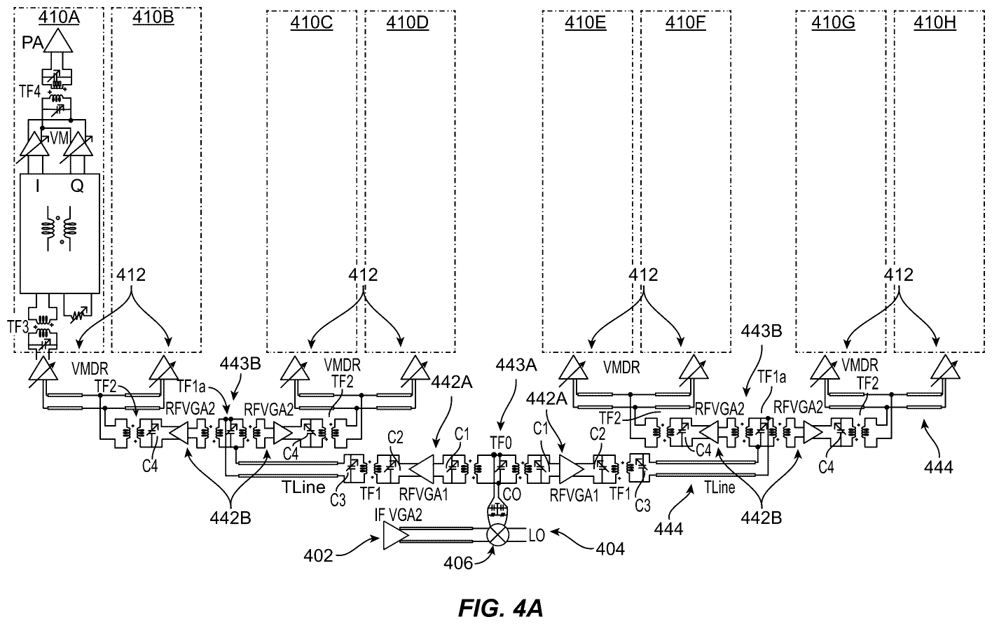

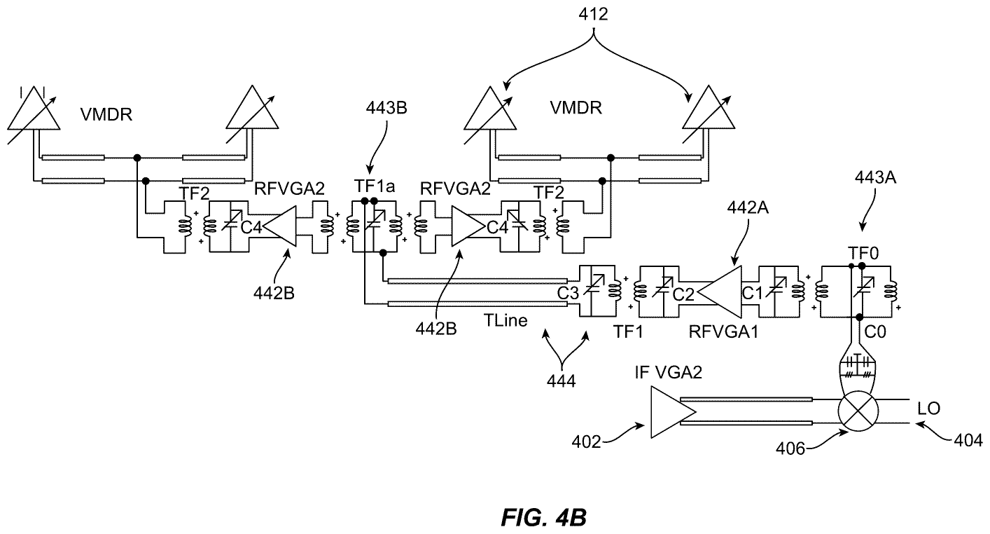

As indicated above, such RF transmission line fanouts and associated parasitics can involve significant resource and performance issues. Aspects described herein include RFVGAs with reduced parasitics to improve overall performance, reduce power consumption, and provide top floorplan flexibility in transmission system design. While aspects described herein are discussed in the context of the illustrated RFVGAs, it will be apparent that such structures can be used with other VGAs, including the illustrated IFVGA 402 of FIG. 4A, VGAs in any part of the receive path, or other VGAs in accordance with aspects described herein.

FIG. 4A is a diagram illustrating aspects of a phased array in which aspects of the present disclosure may be implemented. FIG. 4A can, in some aspects, illustrate a schematic diagram with additional details of the supporting circuitry 340 including the RF transmission line routing path of the transmission system of FIGS. 3A and 3B. Additionally, while FIGS. 3A and 3B represent some elements of a physical layout of the phased array system, with fanouts positioned to generate routing paths with equal or similar transmission line distances to each phase element, FIG. 4A provides additional details of the electrical circuitry of the RF transmission line routing paths. Just as in FIG. 3B, FIG. 4A illustrates a phased array element structure including eight phased array elements (287). In additional aspects, additional routing paths can be added to the illustrated routing structure to create a phased array with any number of symmetrically configured arrays (e.g., 8, 16, 64, 128, 256, 512, etc.). As shown, FIG. 4A includes phased array elements 410A-H, an IFVGA 402, an LO input 404, an input mixer 406, a plurality of RFVGAs 442 and transmission line elements 444, and input vector modulator driver amplifiers (VMDRs) 412 to corresponding phased array elements 410A-H.

FIG. 4B is a diagram illustrating aspects of a phased array in which aspects of the present disclosure may be implemented. FIG. 4B illustrates a portion of the transmission system with routing paths to four of the eight array elements of FIG. 4A (e.g. the routing paths from the IFVGA 402 and the LO input 404 to the phased array elements 410A and 410B (not shown in FIG. 4B).

FIGS. 4A and 4B shows a schematic diagram of a phased array. Each phased array element 410A, 410B, 410C, 410D, 410E, 410F, 410G, 410H can additionally include receive circuitry as illustrated in FIGS. 3A and 3B, which is not shown in FIGS. 4A and 4B. A synthesizer (e.g., one of the phase locked loops (PLL) illustrated in FIGS. 3A and 3B) may be configured to provide a local oscillator (LO) signal to the illustrated mixer of the phased array system at LO input 404, with an IF signal provided from the illustrated IFVGA. The mixer 406 outputs an RF signal to a first intermediate path of the transmission line circuitry, where a first fanout split 443A occurs, with the RF signal provided to two first level RFVGAs 442A in the first fanout path (e.g., one signal going to the left and one to the right in FIGS. 4A, with FIG. 4B only showing the signal going to the left from FIG. 4A).

The signal output from each RFVGA 442 at each path of the fanout drives the signal along an RF transmission line. In the illustrated example of FIGS. 4A and 4B, a transmission line at the output of the first path RFVGAs 442A further splits off into second fanout splits 443B, with each path output from the second fanout splits 443B connected to a second level RFVGA 442B. The outputs of the RFVGAs 442 may be coupled to a transformer (e.g., TF1-TF4) and/or one or more (variable or adjustable) capacitors (e.g., C1-C4). For example, a double tuned transformer may be coupled between the output of an RFVGA 442 and an RF transmission line. For RF transmission systems with more than the illustrated eight phased array elements 410A-H, this transmission line fanout structure can be repeated any number of times to connect the RF signal generated by the mixer 406 to any number of phased array elements. In the illustrated structure of FIGS. 4A and 4B. the second path RFVGAs 442B provide an output that is split and then input to two phased array elements as illustrated, with vector modulator driver amplifiers (VMDRs) 412 at the input to each of the corresponding phased array elements 410A-H.

In some aspects, one or more signals may be received at the IFVGA 402 from IF ports on an RF integrated circuit (RFIC). The signals on these ports may be conveyed over an interconnect from a transceiver chip or other circuitry which generates the one or more signals. Similarly, the transceiver chip may receive data signals used to generate the IF signal from a data processor of a device, such as the device 110 of FIG. 1, which is configured for wireless communications in accordance with aspects described herein.

FIGS. 3A, 3B, 4A, and 4B are described within the context of a system implemented in four quadrants (e.g., with examples described as having symmetrical multiples of two phased array element structures in each quadrant for a total of 8, 16, 64, etc. phased array element structures). In other examples, however, there may not be four such quadrants. For example, in implementations where certain antennas do not include both a V and an H pol, there may be less than four quadrants (e.g., just the upper half of FIG. 3A may be implemented). Further, while the quadrants are illustrated as being distributed in four corners of a rectangle, such representation is not limiting. The quadrants may be arranged on a chip in any number of manners. The phased array element structures may be linearly arranged, or may overlap in different layout implementations.

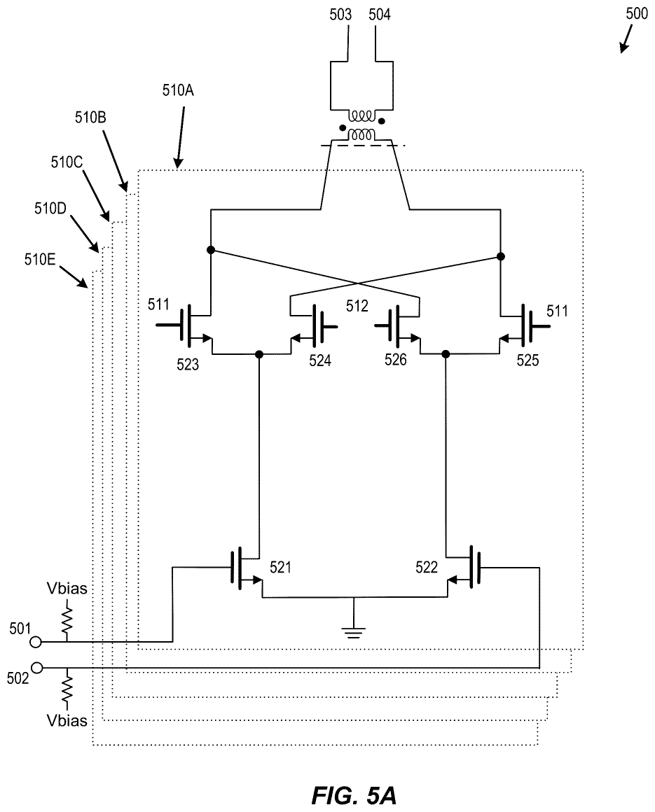

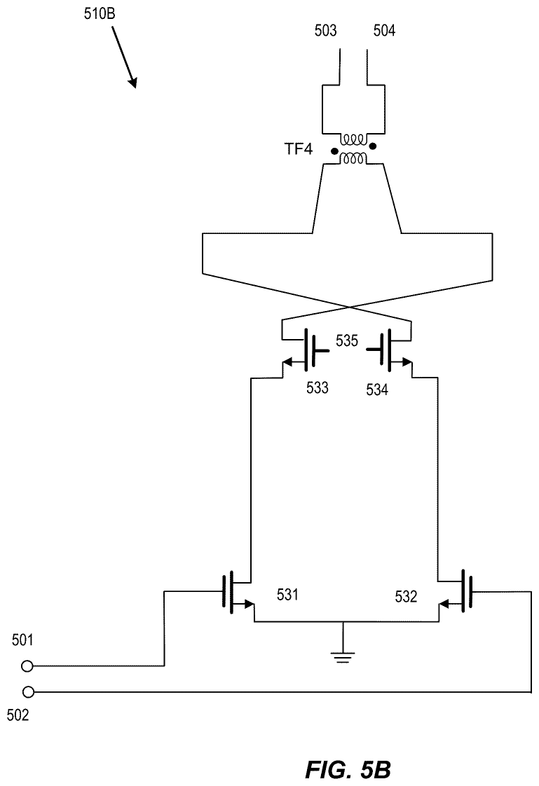

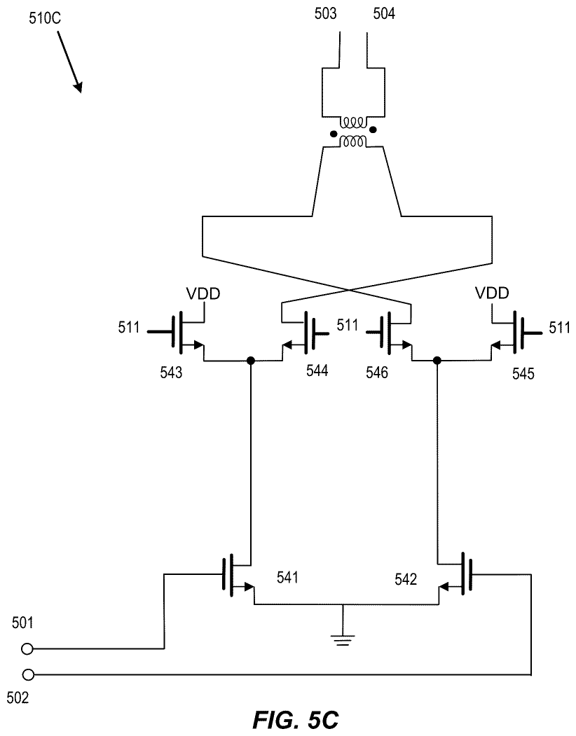

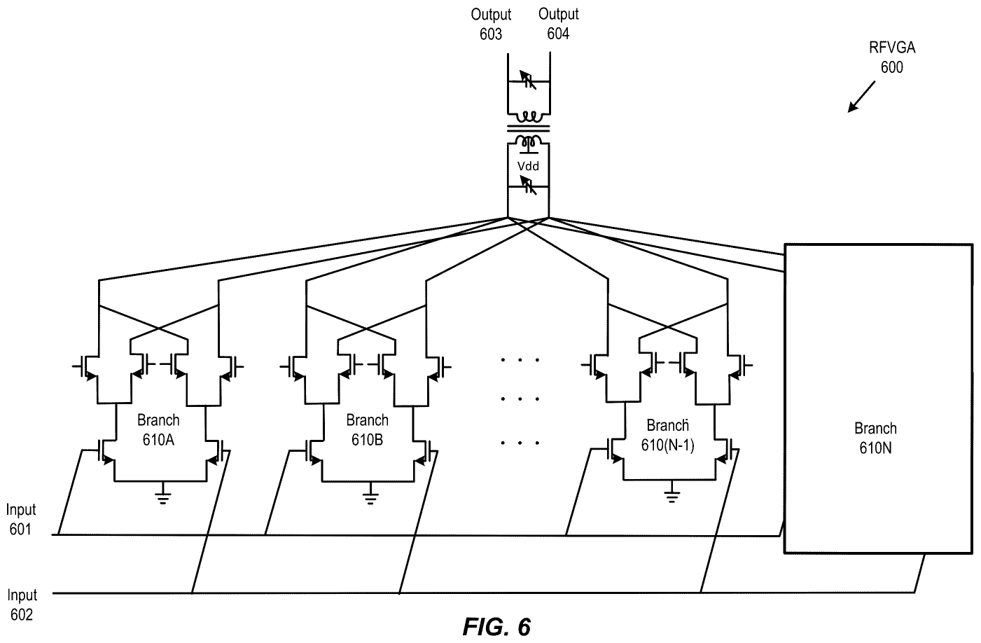

FIG. 5A is a diagram illustrating aspects of a radio frequency (RF) variable gain amplifier (RFVGA) 500 in accordance with aspects of the present disclosure. The RFVGA of FIGS. 5A includes multiple RFVGA units 510A, 510B, 510C, 510D, 510E, illustrated as branches (e.g., 5 illustrated branches in FIG. 5A, and illustrated branches 1 through N in FIGS. 6, 7, 8, and 9A), with a circuit diagram for the RFVGA unit of one of the branches shown in detail (e.g., RFVGA unit 510A illustrated in FIG. 5A). The RFVGA 500 has (RF signal) inputs 501, 502, and provides a differential RF output at outputs 503, 504. The RFVGA 500 can be an implementation of any RFVGA described above, particularly the RFVGAs 442A and 442B in the RF transmission fanouts illustrated in FIGS. 3A, 3B, 4A, and 4B above. In various implementations, any number of RFVGA units can be used in an RFVGA according to aspects described herein, depending on the design details of a particular phased array system. FIGS. 5A, 5B, and 5C each describe different potential implementations of an RFVGA unit (e.g., a different branch of the multiple branches or RFVGA units 510A-E as illustrated in FIG. 5A). Each of the units of FIGS. 5A, 5B, and 5C can be considered to describe a different unit type, with RFVGAs in accordance with aspects described herein composed of units having at least one unit of the type illustrated by FIGS. 5B and 5C and optionally including a combination of different unit types. In accordance with aspects described herein, at least one RFVGA unit will comprise the structure of either FIG. 5B or 5C, and other units of an RFVGA in accordance with aspects described herein can be any of the illustrated circuits of FIGS. 5A, 5B, 5C, or any other such structure.

The circuitry of FIG. 5A includes a differential transconductive transistor pair including transistors 521 and 522, as well as four cascode switch transistors 523, 524, 525, 526. Each transistor comprises an associated gate, source, and drain connected as illustrated. A first transistor 523 has a first gate, a first source, and a first drain, where the first gate is coupled to a first control input 511, and where the first drain is coupled to a first terminal of an output 503. A second transistor 525 has a second gate, a second source, and a second drain, where the second gate is coupled to the first control input 511, and where the second drain is coupled to a second terminal of the output 504. A third transistor 521 has a third gate, a third source, and a third drain, where the third drain is coupled to the first source, and where the third gate is coupled to a first terminal of a differential input 501. A fourth transistor 522 has a fourth gate, a fourth source, and a fourth drain, where the fourth drain is coupled to the second source, and where the fourth gate is coupled to a second terminal of the differential input 502. A fifth transistor 524 has a gate, a source, and a drain, where the gate is coupled to a second control input 512, where the source is coupled to the first source, and where the drain is coupled to the second drain. A sixth transistor 526 has a gate, a source, and a drain, where the gate is coupled to the second control input 512, where the source is coupled to the second source, and where the drain is coupled to the first drain. Transistors 523 and 525, as controlled by the gate control inputs 511, can divert the signal current generated from differential pair of transistors 521, 522 to the output, while transistors 524 526, as controlled by the second control input 512. can divert the signal current from differential pair of transistors 521, 522 but with 180 degree inverted phase to the output. Control inputs 511 and 512 are gain control digital signal inputs which are opposite for each other inside the same branch. Each branch has an associated independent gain control signal. Ctrl <1:N> (e.g., the separate control signal input for each of the N branches) will set the final signal current injecting into the output and thus set the gain of a given RFVGA. The larger the number of branches N in a particular RFVGA, the larger gain control dynamic range the RFVGA can achieve, with improvements in associated RFVGA gain control resolution.

The control inputs (e.g., control nodes or connections to control circuitry) can be used to select when each RFVGA unit of an RFVGA is active and contributing to the output level of the RF signal as it passes through each RFVGA as part of a RF transmission phased array fanout. Turning “on” a given RFVGA unit increases the gain of a given RFVGA (e.g., by summing the phase aligned RF currents from each “on” branch at an output transformer), and turning “off” a given RFVGA unit (e.g., configuring the input signals to cancel at the output transformer between different branches) reduces the gain of the particular RFVGA. In some examples, as described above, elements of the RFVGA may still receive power and/or pass current, but in an opposite phase, in an “off” state. In other examples, elements of the RFVGA may be decoupled from a power or voltage source and/or may not pass current in the “off” state. When implemented in a RF transmission fanout as illustrated in FIGS. 3A, 3B, 4A, and 4B, the RF signal is received at the first and second input nodes, with a bias voltage at the input nodes used to bias the RF signal input to the particular RFVGA unit. The bias voltages are connected to the input nodes via resistive or inductive networks. When an RFVGA branch is selected by the signal at the digital control inputs (e.g., signals applied to cascode switch transistor gates respectively for each branch of an RFVGA), the signal passes through the cascode switch transistors, and is output at the illustrated transformer which converts RF current into RF voltage. The output signal from each RFVGA unit that is selected to an on state are input to the transformer to provide an amplified signal at the output of the transformer with a variable gain determined by the number of RFVGA units in the on state. The size of the transistors in two or more of the RFVGA branches may be different, such that turning on or off different RFVGA units (e.g., the units of FIGS. 5A, 5B, 5C, within a particular RFVGA) adds or removes different amounts of gain to the output signal. In some aspects, scaling (e.g., times two scaling) control signals for all transistors are digitized for RFVGA branches from a low branch to a high branch, so that the RFVGA gain control can be calculated through binary weighting through each branch. As illustrated in the FIG. 5A. regardless of the gain control signals the system is setting (e.g., settings provided to the control inputs via control circuitry), the input and output impedance for each branch and as combined are configured to match and maintain an equivalent phase change regardless of the gain range. Branch matching in a phased array system facilitates performance targets, where the phase relationship for different units can maintain consistency over DOE and temperature, and over a whole phased array gain control dynamic range.

FIG. 5B is a diagram illustrating aspects of an RFVGA in accordance with aspects of the present disclosure. FIG. 5B illustrates an alternative RFVGA unit 510B in accordance with aspects described herein. In particular, transistors 523 and 525 coupled to the control input 511 in FIG. 5A are removed from the circuitry of the RFVGA unit 510B of FIG. 5B. Removing these switch transistors that connect between the source of one transistor and the drain of an adjacent transistor in the design results in a phase immune amplifier unit with reduced parasitics. As described above, a phased array system with a large number of phased array units and RFVGAs in each path of a multipath fanout of a system can have design issues associated with large parasitics at the output. With scaling (e.g., times two scaling) digitized for RFVGA branches and device sizing from the low to the high branch, each RFVGA has an output parasitic cap dominated by all drain parasitic caps of cascode switches (e.g., the transistors 523, 524, 525, and 526 in FIG. 5A). Inclusion of the circuitry of FIG. 5B as a unit of an RFVGA can provide design flexibility due to the reduced parasitics and area when the connecting switch transistors (e.g., most significant bit (MSB) cascode switch transistors 523 and 526, or 524 and 525 alternatively, for example corresponding to a branch for processing a MSB) are removed, while providing sufficient phase immune performance for amplification in driving the RF signal of a phased array system through a transmission fanout.

The RFVGA unit 510B of FIG. 5B includes a differential transconductive transistor pair of transistors 531, 532, as well as two cascode switch transistors 533, 534. The two cascode switch transistors 533, 534 are always on to conduct the differential current generated from the pair of transistors 531, 532 to the terminals of the differential output 503, 504 of the RFVGA unit of FIG. 5B. The transistor 533 has a first gate, a first source, and a first drain, where the first gate is coupled to a control input 535, and where the first drain is coupled to a first terminal of the outputs 503, 504. The transistor 534 has a second gate, a second source, and a second drain, where the second gate is coupled to the control input 535, and where the second drain is coupled to a second terminal of the outputs 503, 504. The transistor 531 has a third gate, a third source, and a third drain, where the third drain is coupled to the first source, and where the third gate is coupled to a first terminal of an input 501. The transistor 532 has a fourth gate, a fourth source, and a fourth drain, where the fourth drain is coupled to the second source, and where the fourth gate is coupled to a second terminal of the input 502. As described and illustrated, the absence of half the cascode (MSB) switches improves power performance, space usage, and other design characteristics by limiting parasitics for signal path splitting in a phased array transmission system.

FIG. 5C is a diagram illustrating aspects of an RFVGA in accordance with aspects of the present disclosure FIG. 5C includes an RFVGA unit 510C configured in a hybrid structure part-way between the RFVGA unit 510A of FIG. 5A and the RFVGA unit 510B of FIG. 5B. In the RFVGA unit 510C of FIG. 5C, the same core structure as above in FIGS. 5A and 5B is presented with two cascode switch transistors present and connected as described in FIG. 5B. In FIG. 5C, however, the RFVGA unit 510C includes a transistor 543 and a transistor 546 with a different connection than what is shown in the RFVGA unit 510A of FIG. 5A. A difference with the RFVGA unit 510A of FIG. 5A is that instead of including cascode switch transistors 523 and 525 implemented for diverting the RF signal to the output transformer, the drains of transistors 543 and 546 in the RFVGA unit 510C are coupled to VDD. In the RFVGA unit 510C of FIG. 5C, cascode switch transistors 544 and 546 can be configured as always “on” and transistors 543 and 545 can be configured as always “off”, with the two always “off” cascode switch transistors 543, 545 connected to the drains of transistors 541 and 542, but with the gates of transistors 543, 545 not connected to the control 511 (in contrast to the example illustrated in FIG. 5C). With such configurations, the RFVGA unit 510C of FIG. 5C can achieve better phase immunity across wide gain control range by maintaining consistent impedance at the drains of transistors 541, 542 than the RFVGA unit 510A illustrated in FIG. 5A.

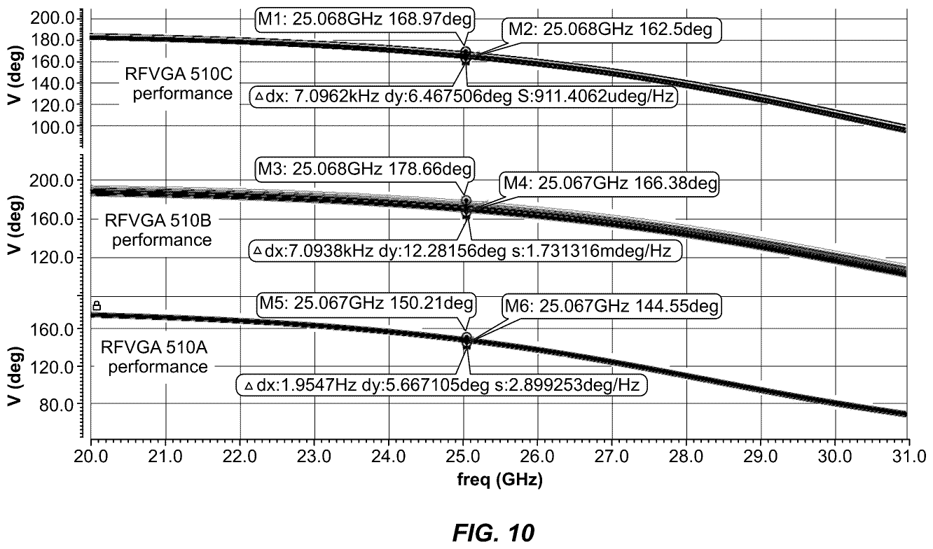

In FIG. 5C, in contrast to the RFVGA unit 510A of FIG. 5A, the additional transistors 543, 545 beyond what are present in the RFVGA unit 510B of FIG. 5B have drains coupled to a power node (e.g., a system voltage, VDD) rather than being cross coupled to drains of adjacent transistors. The RFVGA unit 510C of FIG. 5C provides additional performance improvements when compared with the RFVGA unit of FIG. 5B at a cost of increased space usage. An example performance comparison of the RFVGA units 510A-C of FIGS. 5A, 5B, and 5C is provided in the charts of FIG. 10.

The RFVGA units of FIGS. 5A, 5B, and 5C can then be combined in various combinations to form individual RFVGAs in accordance with aspects described herein, so long as an RFVGA includes at least one unit that is configured to match the circuitry of FIG. 5B or FIG. 5C. Each RFVGA unit of an RFVGA will be positioned in parallel with other RFVGA units of the RFVGA to provide gain performance based on the control settings of each unit, with the outputs of each unit combined. Different numbers of units can be combined in parallel for differing dynamic range and maximum gain, depending on the design of a given implementation. An individual RFVGA in accordance with aspects described herein can include seven instances of the RFVGA unit of FIG. 5A and a single instance of the RFVGA unit of FIG. 5B. The gain of such an RFVGA during operation is set by setting various RFVGA units to an on state (e.g., where the output signals at the transformer of a given RFVGA unit combine) or off state (e.g., where the output signals at the transformer cancel to reduce the overall output power of the RFVGA). Another implementation of an RFVGA can include 31 instances of the RFVGA unit of FIG. 5A, and a single instance of the RFVGA unit of FIG. 5C. Still a further implementation can include 64 instances of the RFVGA unit of FIG. 5B, and no instance of any other RFVGA unit. Still further implementations can use RFVGA units different than the RFVGA units illustrated, so long as one or more of the RFVGA units in the RFVGA include at least one instance of either the RFVGA unit of FIG. 5B or the RFVGA unit of FIG. 5C. Inclusion of additional instances of the RFVGA unit of FIG. 5B reduces the gain control and increases phase variation, with lower power consumption, space usage, and parasitics than instances of the RFVGA unit of FIG. 5A. Inclusion of additional instances of the RFVGA unit of FIG. 5B provides intermediate benefits between the design of FIGS. 5A and 5B.

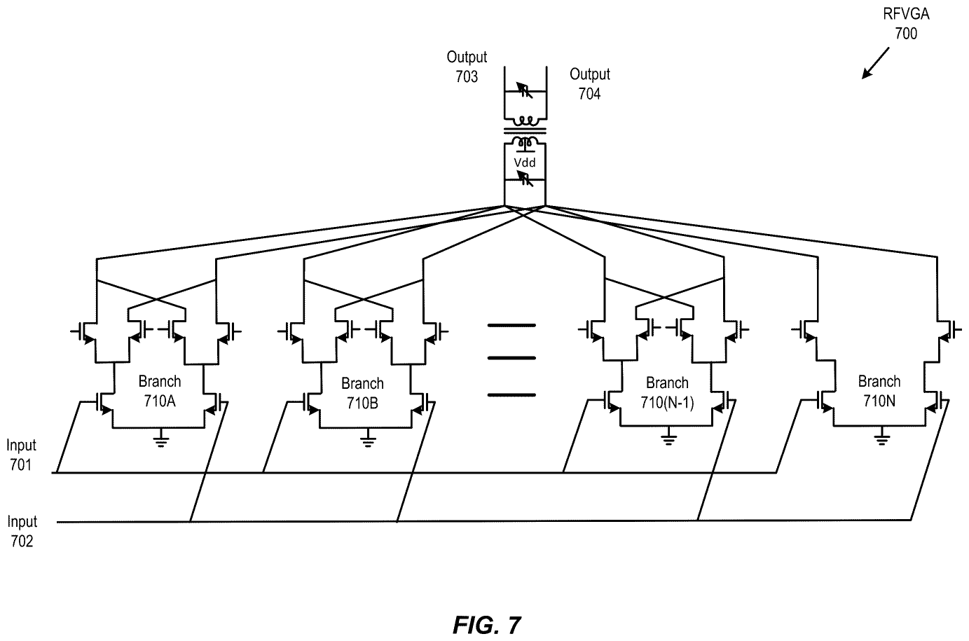

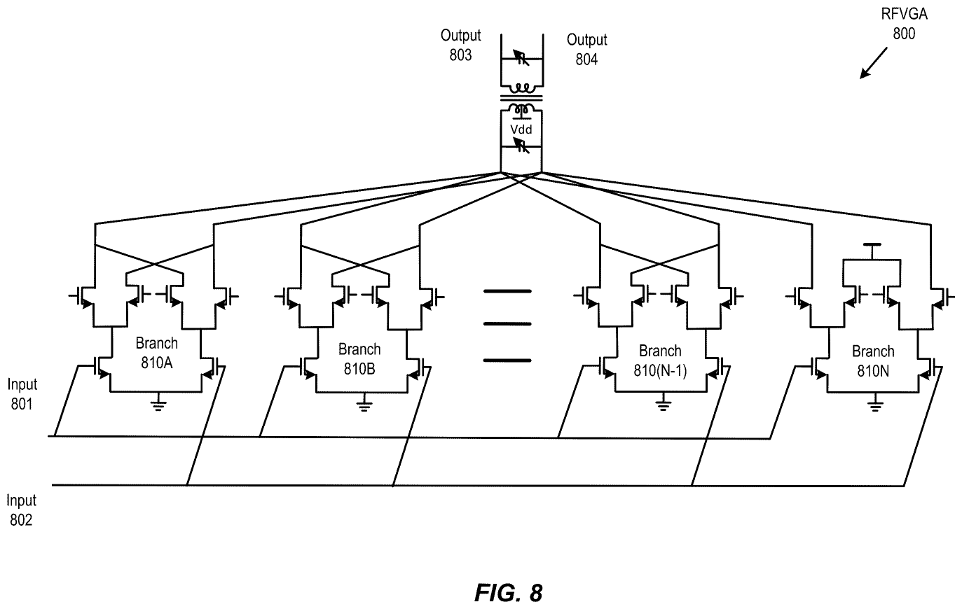

FIG. 6 is a diagram illustrating aspects of an RFVGA 600 in accordance with aspects of the present disclosure. The RFVGA 600 has (RF signal) inputs 601 and 602, and connections for differential output 603, 604. As illustrated in FIG. 5A above, a VGA in accordance with aspects described herein includes multiple branches (e.g., units). FIG. 6 illustrates an RFVGA 600 with N branches (e.g., RFVGA units) labeled as branches 610A-N, where branches 610A through 610(N-1) are VGA units as described in FIG. 5A. Branch 610N can be an implementation of either the VGA unit of FIG. 5B, or the VGA unit of FIG. 5C, as illustrated in FIGS. 7 and 8. In FIG. 6, the branches 610A through (N-1) include both cascode control switching and tunable MSB cross switching, where the cross cascode switching in the Nth branch is optional, depending on which unit is implemented (e.g., no fine tunable MSB switching with the option of FIG. 5B). In other examples, more than one branch may implement the VGA unit of FIG. 5B or FIG. 5C. For example, both the (N-1)th branch and the Nth branch can implement the VGA unit of FIG. 5C, or the 1^{st} branch can implement the VGA unit of FIG. 5C and the Nth branch can implement the VGA unit of FIG. 5B.

FIG. 7 is a diagram illustrating aspects of an RFVGA 700 in accordance with aspects of the present disclosure. FIG. 7 illustrates FIG. 6 with the Nth branch 710N implemented as a copy of the VGA unit of FIG. 5B described above. In accordance with aspects described above, the RFVGA 700 of FIG. 7 includes connections for (RF signal) inputs 701, 702 and output 703, 704. The RFVGA 700 includes cascode switching for all N branches 710A through 71ON to allow variable gain control. Branches 710A through 710(N-1) also include MSB switching, while the Nth branch 710N does not, reducing space usage and power usage of the design, and potentially causing a reduction in phase performance (e.g., as described below in the chart of FIG. 10) while maintaining phase performance within acceptable design parameters.

FIG. 8 is a diagram illustrating aspects of an RFVGA 800 in accordance with aspects of the present disclosure. FIG. 8 illustrates an implementation of the RFVGA 600 of FIG. 6 modified with the Nth branch 810N of the RFVGA 800 implemented as a copy of the VGA unit of FIG. 5C described above. The RFVGA 800 of FIG. 8 includes cascode switching for all branches 810A through N as well as MSB switching for all branches 810A through 810N, with (RF signal) inputs 801, 802 and connections for differential output 803. 804. The configuration of the Nth branch 810N of the RFVGA 800 reduces parasitics and potentially causes a slight reduction in phase performance (e.g., as described below in the chart of FIG. 10) while maintaining phase performance within acceptable design parameters.

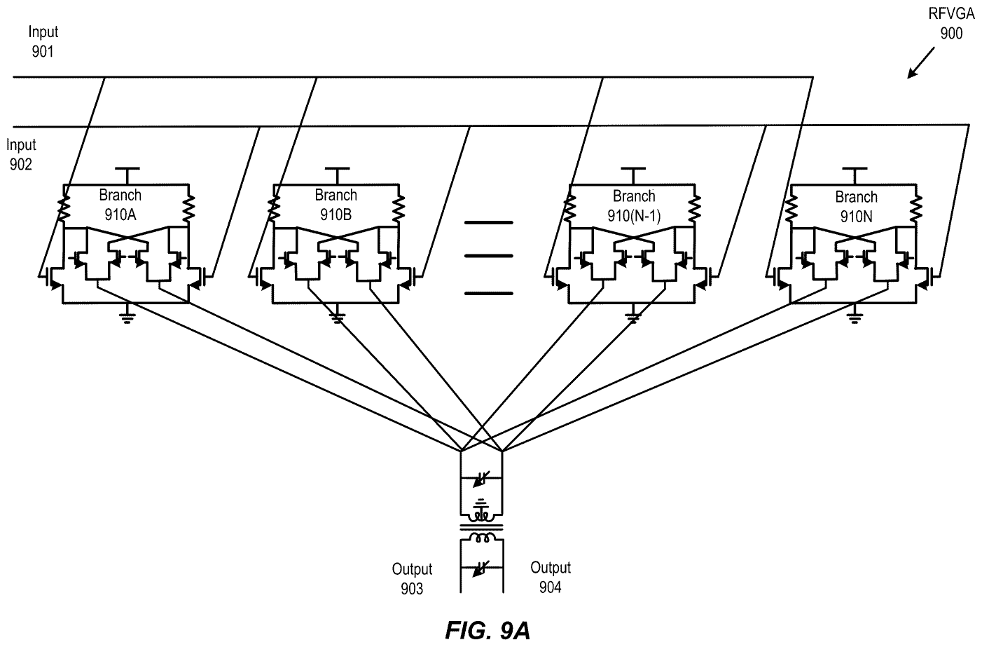

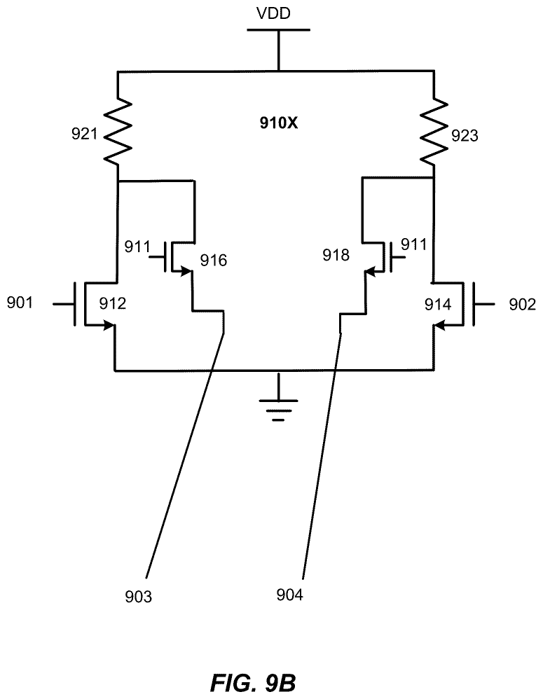

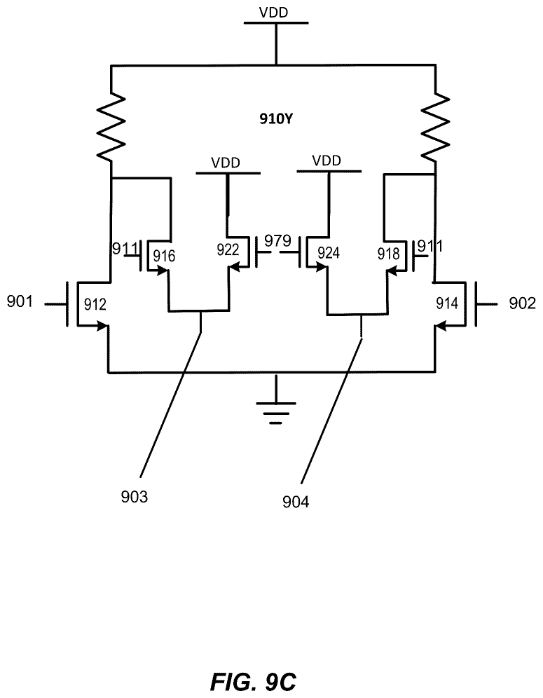

FIG. 9A is a diagram illustrating aspects of an RFVGA 900 in a “folded” configuration in accordance with aspects of the present disclosure. The RFVGA of FIG. 9A operates under similar principles with the RFVGAs described above, with lowered power consumption. As shown, the RFVGA 900 includes (RF signal) inputs 901 and 902. Control inputs (described below) of the RFVGA branches 910A through 910N may vary the gain of the RFVGA 900 in accordance with the operations described above. The RF signal from the RFVGA 900 is provided as a differential signal at output 903, 904.

FIG. 9B illustrates an RFVGA unit 910X in a folded configuration that corresponds to the non-folded RFVGA unit of FIG. 5B. FIG. 9C illustrates and RFVGA unit in a folded configuration that corresponds to the non-folded RFVGA unit of FIG. 5C. The RFVGA units of FIGS. 9B and 9C can be implemented in one or more branches of the RFVGA of FIG. 9A to modify design performance in a fashion consistent with the descriptions above, but for a “folded” low power implementation. With the “folded” RFVGA configuration, the supply voltage may not support two series cascode operation, and thus can be reduced by 30-40% (e.g., 0.9V to 0.6V). The downside with such a folded configuration can be an area penalty with an extra resistor on the drain thus taking more silicon area, with a potential IR drop that can constrain linearity. Such a folded configuration can provide more benefit for receiver or other lower linearity requirement block applications.

In some aspects, FIG. 9B describes a folded unit of a radio frequency (RF) variable gain amplifier (VGA) 910X, where the RFVGA unit 910X comprises a first transistor 912 comprising a first gate, a first source, and a first drain, where the first gate is coupled to the input 901, where the first source is coupled to a reference voltage (e.g., ground), and where the first drain is coupled to a voltage source VDD (or supply voltage) via a first resistive element 921; a second transistor 914 comprising a second gate, a second source, and a second drain, where the second gate is coupled to the input 902, where the second source is coupled to the reference voltage and where the first drain is coupled to the voltage source VDD via a second resistive element 923; a third transistor 916 including a third gate, a third source, and a third drain, where the third drain is coupled to the first drain of the first transistor 912, and where the third gate is coupled to a control input 911; and a fourth transistor 918 comprising a fourth gate, a fourth source, and a fourth drain, where the fourth drain is coupled to the second drain, and where the fourth gate is coupled to the control input 911. The third source of the third transistor 916 is coupled to a first terminal of an output (e.g., output 903), and where the fourth source of the fourth transistor 918 is coupled to a second terminal of the output (e.g., output 904). Similar to the unfolded RFVGA units of FIGS. 5B and 5C, the RFVGA unit of FIG. 9B does not include the cross coupled transistors of other units illustrated in FIG. 9A (e.g., the units in branches 1, 2, N-1, etc.), and the units of FIGS. 9B or 9C are implemented in place of one or more of the units in the N branches illustrated in FIG. 9A.

FIG. 9C illustrates another RFVGA unit 910Y in a folded configuration similar to the unit of FIG. 9B, with the addition of a fifth transistor 922 including a fifth gate, a fifth source, and a fifth drain. The fifth drain is coupled to the voltage source VDD, the fifth gate is coupled to a second control input 979, and the fifth source is coupled to the third source of the third transistor 916 and the first output 903. The RFVGA unit 910Y further includes a sixth transistor 924 comprising a sixth gate, a sixth source, and a sixth drain. The sixth drain is coupled to the voltage source VDD, the sixth gate is coupled to the second control input 979, and the sixth source is coupled to the fourth source of the fourth transistor 918 and the second output 904. In some examples, control inputs 911 and 979 are gain control digital signal inputs which are opposite for each other inside the same branch. In some examples, the drain of the transistor 922 is connected to the drain of transistor 918 instead of to the voltage source, and the drain of the transistor 924 is connected to the drain of transistor 916 instead of to the voltage source.

FIG. 10 is a chart illustrating phase performance aspects of units of the RFVGA unit 510A of FIG. 5A, the RFVGA unit 510B of FIG. 5B, and the RFVGA unit 510C of FIG. 5C in accordance with aspects of the present disclosure. The chart of FIG. 10 shows modeled phase performance for the RFVGA units 510A-C described above, shown as phase variation in degrees on the y-axis, and frequency from 20 to 30 gigahertz on the x-axis. FIG. 10 illustrates that minimal impact on phase variation is present over the coarse and fine gain control options for the various RFVGA units 510A-C illustrated in FIGS. 5A-C. Phase variation within the RF transmission line fanout illustrated in FIGS. 3A, 3B, 4A, and 4B is a performance characteristic that can result in design failure if more than an approximately plus or minus 10 degree phase shift occurs with the 40-50 decibel (dB) dynamic range provided by an RFVGA. A greater phase variation can cause performance failure in a design, and failure to meet operation performance targets. Each of the RFVGA units 510A-C in FIGS. 5A-5C provide acceptable phase performance capable of meeting phase variation targets in a design, while providing design flexibility to adjust space usage, parasitic characteristics, and power usage when the RFVGA units 510A-C are combined within an RFVGA. The phase performance of the RFVGA units 510B and 510C of FIGS. 5B and 5C, while lower than the RFVGA unit 510A of FIG. 5A, still can provide acceptable phase performance when combined as branches of an RFVGA, as illustrated in the charts of FIGS. 10.

The use of RFVGAs including different combinations of the illustrated RFVGA units can provide high dynamic range in the transmission signal path to meet design specifications between a minimum power and a rated power with acceptable phase variation (e.g., phase immune VGA performance), and can enable an emission resilient design without a post power amplifier (PA) filter at the phased array element connection to the antenna (e.g., at the output of the PAs in FIGS. 3A and 3B, or at the output of the PA in the detailed phased array element of FIG. 4A).

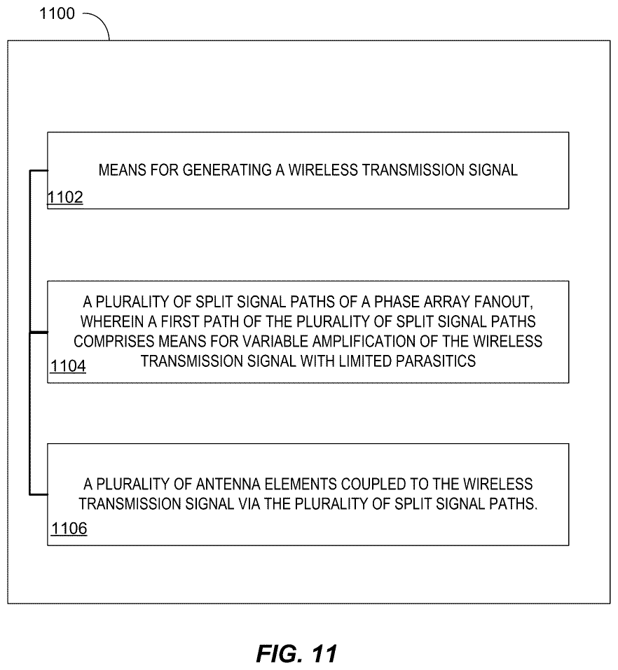

FIG. 11 is a functional block diagram of an apparatus 1100 including RFVGAs in a transmission path of a phased array in accordance with some aspects. The apparatus 1100 comprises means 1102 for generating a wireless transmission signal, means 1104 comprising a plurality of split signal paths of a phased array fanout coupled to the means for generating the wireless transmission signal, wherein a first path of the plurality of split signal paths comprises means 1104 for variable amplification of the wireless transmission signal with limited parasitics, and means 1106 comprising a plurality of antenna elements coupled to the plurality of split signal paths.

Devices, networks, systems, and certain means for transmitting or receiving signals described herein may be configured to communicate via one or more portions of the electromagnetic spectrum. The electromagnetic spectrum is often subdivided, based on frequency or wavelength, into various classes, bands, channels, etc. In 5G NR two initial operating bands have been identified as frequency range designations FR1 (410 MHz- 7.125 GHz) and FR2 (24.25 GHz-52.6 GHz). The frequencies between FR1 and FR2 are often referred to as mid-band frequencies. Although a portion of FR1 is greater than 6 GHz, FR1 is often referred to (interchangeably) as a “sub-6 GHz” band in various documents and articles, and will be referred to herein as “sub-7 GHz”. A similar nomenclature issue sometimes occurs with regard to FR2, which is often referred to (interchangeably) as a “millimeter wave” (mmW) band in documents and articles, despite including frequencies outside of the extremely high frequency (EHF) band (30 GHz-300 GHz) which is identified by the International Telecommunications Union (ITU) as a “mmWave” or mmW band. Aspects described herein can operate in such frequency ranges, and can also be implemented in other frequency ranges. For example, VGAs described herein can be used in FR2 IF frequency ranges, or other such frequency ranges.

With the above aspects in mind, unless specifically stated otherwise, it should be understood that the term “sub-7 GHz” or the like if used herein may broadly represent frequencies that may be less than 7 GHz, may be within FR1, or may include mid-band frequencies. Further, unless specifically stated otherwise, it should be understood that the term “mmWave”, mmW, or the like if used herein may broadly represent frequencies that may include mid-band frequencies, may be within FR2, or may be within the EHF band.

The circuit architecture described herein may be implemented on one or more ICs, analog ICs, mmWICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR) or corresponding mmW elements, (iv) an ASIC such as a mobile station modem (MSM), (v) a module that may be embedded within other devices, (vi) a receiver, cellular phone, wireless device, handset, or mobile unit, (vii) etc.

The phrase “coupled to” and the term “coupled” refers to any component that is physically connected to another component either directly or indirectly, and/or any component that is in communication with another component (e.g., connected to the other component over a wired or wireless connection, and/or other suitable communication interface) either directly or indirectly.

Generally, where there are operations illustrated in figures, those operations may have corresponding counterpart means-plus-function components with similar numbering.

As used herein, the term “determining” encompasses a wide variety of actions. For some aspects, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

Although selected aspects have been illustrated and described in detail, it will be understood that various substitutions and alterations may be made therein without departing from the spirit and scope of the present invention, as defined by the following claims.

The following is a set of non-exclusive aspects in accordance with the innovations provided herein.

Aspect 1. A radio frequency (RF) variable gain amplifier (VGA) comprising: a first transistor comprising a first gate, a first source, and a first drain, wherein the first gate is coupled to a control input, and wherein the first drain is coupled to a first terminal of an output; a second transistor comprising a second gate, a second source, and a second drain, wherein the second gate is coupled to the control input, and wherein the second drain is coupled to a second terminal of the output; a third transistor comprising a third gate, a third source, and a third drain, wherein the third drain is coupled to the first source, and wherein the third gate is coupled to a first terminal of an input; and a fourth transistor comprising a fourth gate, a fourth source, and a fourth drain, wherein the fourth drain is coupled to the second source, and wherein the fourth gate is coupled to a second terminal of the input; wherein the first source is not connected to the second drain via one or more transistors, and wherein the second source is not connected to the second drain via one or more transistors.

Aspect 2. The RFVGA of Aspect 1, comprising a plurality of VGA units wherein the first transistor, the second transistor, the third transistor, and the fourth transistor comprise a first VGA unit, wherein the first source is not connected to the second drain via one or more transistors, and wherein the second source is not connected to the second drain via one or more transistors to limit parasitics for signal path splitting, wherein half the plurality of VGA units include most significant bit (MSB) switches, and wherein each VGA unit of the plurality of VGA units includes cascode control switching.

Aspect 3. The RFVGA of any of Aspects 1 to 2, further comprising a transformer comprising a first input, a second input, a first output, and a second output, wherein the first input is coupled to the first terminal of the output, wherein the second input is coupled to the second terminal of the output.

Aspect 4. The RFVGA of any of Aspects 1 to 3, wherein the third source and the fourth source are coupled to a reference voltage node.

Aspect 5. The RFVGA of any of Aspects 1 to 4, further comprising: a fifth transistor comprising a fifth source, a fifth drain, and a fifth gate, wherein the fifth source is coupled to the first source, wherein the fifth gate is coupled to a second control input, and wherein the fifth drain is coupled to a voltage power node; and a sixth transistor comprising a sixth source, a sixth drain, and a sixth gate, wherein the sixth source is coupled to the second source, wherein the sixth gate is coupled to the second control input, and wherein the sixth drain is coupled to the voltage power node.

Aspect 6. The RFVGA of any of Aspects 1 to 5, further comprising a plurality of parallel VGA amplifier units, wherein a first unit of the plurality of parallel VGA amplifier units comprises the first transistor, the second transistor, the third transistor, and the fourth transistor.

Aspect 7. The RFVGA of any of Aspects 1 to 6, wherein a second unit of the plurality of parallel VGA amplifier units comprises: a first transistor comprising a first gate, a first source, and a first drain, wherein the first gate is coupled to a third control input, and wherein the first drain is coupled to a first terminal of an output; a second transistor comprising a second gate, a second source, and a second drain, wherein the second gate is coupled to the third control input, and wherein the second drain is coupled to a second terminal of the output; a third transistor comprising a third gate, a third source, and a third drain, wherein the third drain is coupled to the first source, and wherein the third gate is coupled to a first terminal of an input; a fourth transistor comprising a fourth gate, a fourth source, and a fourth drain, wherein the fourth drain is coupled to the second source, and wherein the fourth gate is coupled to a second terminal of the input; a fifth transistor comprising a gate, a source, and a drain, wherein the gate is coupled to a a fourth control input, wherein the source is coupled to the first source, and wherein the drain is coupled to the second drain; and a sixth transistor comprising a gate, a source, and a drain, wherein the gate is coupled to the fourth control input, wherein the source is coupled to the second source, and wherein the drain is coupled to the first drain.

Aspect 8. The RFVGA of any of Aspects 1 to 7 wherein the plurality of parallel VGA amplifier units includes a first plurality of units of a first type comprising the first unit, and a second plurality of units of a second type comprising the second unit.

Aspect 9. The RFVGA of any of Aspects 1 to 8, wherein the first terminal of the input is coupled to a first bias node via a first resistive element, and wherein the second terminal of the input is coupled to a second bias node via a second resistive element.

Aspect 10. The RFVGA of any of Aspects 1 to 9, wherein the RFVGA is configured in a first path of a split transmission path of a phased array transmission sy stem.

Aspect 11. The RFVGA of any of Aspects 1 to 10, wherein the first transistor and the second transistor are not connected via cross coupled MSB switches.

Aspect 12. A wireless communication apparatus comprising: a phased array transmission circuit comprising a plurality of split signal paths, wherein a first path of the plurality of split signal paths comprises a first radio frequency (RF) variable gain amplifier (VGA), the first RFVGA comprising: a first transistor comprising a first gate, a first source, and a first drain, wherein the first gate is coupled to a control input, and wherein the first drain is coupled to a first terminal of an output; a second transistor comprising a second gate, a second source, and a second drain, wherein the second gate is coupled to the control input, and wherein the second drain is coupled to a second terminal of the output; a third transistor comprising a third gate, a third source, and a third drain, wherein the third drain is coupled to the first source, and wherein the third gate is coupled to a first terminal of an input; and a fourth transistor comprising a fourth gate, a fourth source, and a fourth drain, wherein the fourth drain is coupled to the second source, and wherein the fourth gate is coupled to a second terminal of the input; wherein the first source is not connected to the second drain via one or more transistors, and wherein the second source is not connected to the second drain via one or more transistors.

Aspect 13. The wireless communication apparatus of Aspect 12, further comprising: transceiver circuitry coupled to the first terminal of the input and the second terminal of the input; and an antenna element coupled to the first terminal of the output and the second terminal of the output.

Aspect 14. The wireless communication apparatus of any of Aspects 12 to 13, further comprising a plurality of VGA units, wherein the first transistor, the second transistor, the third transistor, and the fourth transistor comprise a first VGA unit, wherein the first source is not connected to the second drain via one or more transistors, and wherein the second source is not connected to the second drain via one or more transistors to limit parasitics for signal path splitting, wherein half the plurality of VGA units include MSB switches, and wherein each VGA unit of the plurality of VGA units includes cascode control switching.

Aspect 15. The wireless communication apparatus of any of Aspects 12 to 14, wherein a second VGA unit of the plurality of VGA units comprises: a first transistor comprising a first gate, a first source, and a first drain, wherein the first gate is coupled to a third control input, and wherein the first drain is coupled to a first terminal of an output; a second transistor comprising a second gate, a second source, and a second drain, wherein the second gate is coupled to the third control input, and wherein the second drain is coupled to a second terminal of the output; a third transistor comprising a third gate, a third source, and a third drain, wherein the third drain is coupled to the first source, and wherein the third gate is coupled to a first terminal of an input; a fourth transistor comprising a fourth gate, a fourth source, and a fourth drain, wherein the fourth drain is coupled to the second source, and wherein the fourth gate is coupled to a second terminal of the input; a fifth transistor comprising a gate, a source, and a drain, wherein the gate is coupled to a fourth control input, wherein the source is coupled to the first source, and wherein the drain is coupled to the second drain; and a sixth transistor comprising a gate, a source, and a drain, wherein the gate is coupled to the fourth control input, wherein the source is coupled to the second source, and wherein the drain is coupled to the first drain.

Aspect 16. The wireless communication apparatus of any of Aspects 12 to 15, wherein the plurality of VGA units includes a first plurality of units of a first type comprising the first VGA unit, and a second plurality of units of a second type comprising the second VGA unit.

Aspect 17. The wireless communication apparatus of any of Aspects 12 to 16, further comprising a transformer comprising a first input, a second input, a first output, and a second output, wherein the first input is coupled to the first output, wherein the second input is coupled to the second output.

Aspect 18. The wireless communication apparatus of any of Aspects 12 to 17, wherein the third source and the fourth source are coupled to a reference voltage node.

Aspect 19. The wireless communication apparatus of any of Aspects 12 to 18, further comprising: a fifth transistor comprising a fifth source, a fifth drain, and a fifth gate, wherein the fifth source is coupled to the first source, wherein the fifth gate is coupled to a second control input, and wherein the fifth drain is coupled to a voltage power node; and a sixth transistor comprising a sixth source, a sixth drain, and a sixth gate, wherein the sixth source is coupled to the second source, wherein the sixth gate is coupled to the second control input, and wherein the sixth drain is coupled to the voltage power node.

Aspect 20. The wireless communication apparatus of any of Aspects 12 to 19, further comprising a plurality of VGA units, wherein a first unit of the plurality of VGA units comprises the first transistor, the second transistor, the third transistor, and the fourth transistor.

Aspect 21. The wireless communication apparatus of any of Aspects 12 to 20, wherein the first terminal of the input is coupled to a first bias node via a first resistive element, and wherein the second terminal of the input is coupled to a second bias node via a second resistive element.

Aspect 22. The wireless communication apparatus of any of Aspects 12 to 21, wherein the RFVGA is configured in a first path of a split transmission path of a phased array transmission system.

Aspect 23. The wireless communication apparatus of any of Aspects 12 to 22, wherein the first transistor and the second transistor are not connected via cross coupled MSB switches.

Aspect 24. A wireless communication apparatus, comprising: means for generating a wireless transmission signal; a plurality of split signal paths of a phased array fanout coupled to the means for generating the wireless transmission signal, wherein a first path of the plurality of split signal paths comprises means for variable amplification of the wireless transmission signal with limited parasitics; and a plurality of antenna elements coupled to the plurality of split signal paths.

Aspect 25. A radio frequency (RF) variable gain amplifier (VGA) including an RFVGA unit in a folded configuration, the RFVGA unit comprising: a first transistor comprising a first gate, a first source, and a first drain, wherein the first gate is coupled to a control input, wherein the first source is coupled to a first terminal of an output, and wherein the first drain is coupled to a voltage source via a first resistive element; a second transistor comprising a second gate, a second source, and a second drain, wherein the second gate is coupled to the control input, wherein the second source is coupled to a second terminal of the output and wherein the second drain is coupled to the voltage source via a second resistive element; a third transistor comprising a third gate, a third source, and a third drain, wherein the third drain is coupled to the first drain, and wherein the third gate is coupled to a first terminal of an input; and a fourth transistor comprising a fourth gate, a fourth source, and a fourth drain, wherein the fourth drain is coupled to the second drain, and wherein the fourth gate is coupled to a second terminal of the input.

Aspect 26. The RFVGA unit of Aspect 25, wherein the third source is coupled to a reference voltage, and wherein the fourth source is coupled to the reference voltage.

Aspect 27. The RFVGA unit of any of Aspects 25 to 26, wherein the RFVGA unit further comprises: a fifth transistor comprising a fifth gate, a fifth source, and a fifth drain, wherein the fifth drain is coupled to the voltage source, the fifth gate is coupled to a second control input, and wherein the fifth source is coupled to the first source of the first transistor and to the first terminal of the output; and a sixth transistor comprising a sixth gate, a sixth source, and a sixth drain, wherein the sixth drain is coupled to the supply voltage, the sixth gate is coupled to the second control input, and wherein the sixth source is coupled to the second source of the second transistor and to the second terminal of the output.

Aspect 28. A device comprising means for variable gain amplification in accordance with any aspect herein.

Aspect 29. A method for operating a variable gain amplifier in accordance with any aspect herein.

Aspect 30. A computer readable storage medium comprising instructions that, when executed by one or more processors of a device, cause the device to perform operations for variable gain amplification in accordance with any aspect herein.

1. A radio frequency (RF) variable gain amplifier (VGA) comprising:
a first transistor comprising a first gate, a first source, and a first drain, wherein the first gate is coupled to a control input, and wherein the first drain is coupled to a first terminal of an output;
a second transistor comprising a second gate, a second source, and a second drain, wherein the second gate is coupled to the control input, and wherein the second drain is coupled to a second terminal of the output;
a third transistor comprising a third gate, a third source, and a third drain, wherein the third drain is coupled to the first source, and wherein the third gate is coupled to a first terminal of an input; and
a fourth transistor comprising a fourth gate, a fourth source, and a fourth drain, wherein the fourth drain is coupled to the second source, and wherein the fourth gate is coupled to a second terminal of the input;
wherein the first source is not connected to the second drain via one or more transistors, and wherein the second source is not connected to the second drain via one or more transistors.

2. The RFVGA of claim 1, comprising a plurality of VGA units, wherein the first transistor, the second transistor, the third transistor, and the fourth transistor comprise a first VGA unit, wherein the first source is not connected to the second drain via one or more transistors, and wherein the second source is not connected to the second drain via one or more transistors to limit parasitics for signal path splitting, wherein half the plurality of VGA units include most significant bit (MSB) switches, and wherein each VGA unit of the plurality of VGA units includes cascode control switching.

3. The RFVGA of claim 1, further comprising a transformer comprising a first input, a second input, a first output, and a second output, wherein the first input is coupled to the first terminal of the output, wherein the second input is coupled to the second terminal of the output.

4. The RFVGA of claim 1, wherein the third source and the fourth source are coupled to a reference voltage node.

5. The RFVGA of claim 1, further comprising:
a fifth transistor comprising a fifth source, a fifth drain, and a fifth gate, wherein the fifth source is coupled to the first source, wherein the fifth gate is coupled to a second control input, and wherein the fifth drain is coupled to a voltage power node; and
a sixth transistor comprising a sixth source, a sixth drain, and a sixth gate, wherein the sixth source is coupled to the second source, wherein the sixth gate is coupled to the second control input, and wherein the sixth drain is coupled to the voltage power node.

6. The RFVGA of claim 1, further comprising a plurality of parallel VGA amplifier units, wherein a first unit of the plurality of parallel VGA amplifier units comprises the first transistor, the second transistor, the third transistor, and the fourth transistor.

7. The RFVGA of claim 6, wherein a second unit of the plurality of parallel VGA amplifier units comprises:
a first transistor comprising a first gate, a first source, and a first drain, wherein the first gate is coupled to a third control input, and wherein the first drain is coupled to a first terminal of an output;
a second transistor comprising a second gate, a second source, and a second drain, wherein the second gate is coupled to the third control input, and wherein the second drain is coupled to a second terminal of the output;
a third transistor comprising a third gate, a third source, and a third drain, wherein the third drain is coupled to the first source, and wherein the third gate is coupled to a first terminal of an input;
a fourth transistor comprising a fourth gate, a fourth source, and a fourth drain, wherein the fourth drain is coupled to the second source, and wherein the fourth gate is coupled to a second terminal of the input;
a fifth transistor comprising a gate, a source, and a drain, wherein the gate is coupled to a fourth control input, wherein the source is coupled to the first source, and wherein the drain is coupled to the second drain; and
a sixth transistor comprising a gate, a source, and a drain, wherein the gate is coupled to the fourth control input, wherein the source is coupled to the second source, and wherein the drain is coupled to the first drain.

8. The RFVGA of claim 7 wherein the plurality of parallel VGA amplifier units includes a first plurality of units of a first type comprising the first unit, and a second plurality of units of a second type comprising the second unit.

9. The RFVGA of claim 1, wherein the first terminal of the input is coupled to a first bias node via a first resistive element, and wherein the second terminal of the input is coupled to a second bias node via a second resistive element.

10. The RFVGA of claim 1, wherein the RFVGA is configured in a first path of a split transmission path of a phased array transmission system.

11. The RFVGA of claim 1, wherein the first transistor and the second transistor are not connected via cross coupled most significant bit (MSB) switches.

12. A wireless communication apparatus comprising:
a phased array transmission circuit comprising a plurality of split signal paths, wherein a first path of the plurality of split signal paths comprises a first radio frequency (RF) variable gain amplifier (VGA), the first RFVGA comprising:
a first transistor comprising a first gate, a first source, and a first drain, wherein the first gate is coupled to a control input, and wherein the first drain is coupled to a first terminal of an output;
a second transistor comprising a second gate, a second source, and a second drain, wherein the second gate is coupled to the control input, and wherein the second drain is coupled to a second terminal of the output;
a third transistor comprising a third gate, a third source, and a third drain, wherein the third drain is coupled to the first source, and wherein the third gate is coupled to a first terminal of an input; and
a fourth transistor comprising a fourth gate, a fourth source, and a fourth drain, wherein the fourth drain is coupled to the second source, and wherein the fourth gate is coupled to a second terminal of the input;
wherein the first source is not connected to the second drain via one or more transistors, and wherein the second source is not connected to the second drain via one or more transistors.

13. The wireless communication apparatus of claim 12, further comprising:
transceiver circuitry coupled to the first terminal of the input and the second terminal of the input; and
an antenna element coupled to the first terminal of the output and the second terminal of the output.

14. The wireless communication apparatus of claim 12, further comprising a plurality of VGA units, wherein the first transistor, the second transistor, the third transistor, and the fourth transistor comprise a first VGA unit, wherein the first source is not connected to the second drain via one or more transistors, and wherein the second source is not connected to the second drain via one or more transistors to limit parasitics for signal path splitting, wherein half the plurality of VGA units include MSB switches, and wherein each VGA unit of the plurality of VGA units includes cascode control switching.

15. The wireless communication apparatus of claim 12, wherein the third source and the fourth source are coupled to a reference voltage node.

16. The wireless communication apparatus of claim 12, further comprising:
a fifth transistor comprising a fifth source, a fifth drain, and a fifth gate, wherein the fifth source is coupled to the first source, wherein the fifth gate is coupled to a second control input, and wherein the fifth drain is coupled to a voltage power node; and
a sixth transistor comprising a sixth source, a sixth drain, and a sixth gate, wherein the sixth source is coupled to the second source, wherein the sixth gate is coupled to the second control input, and wherein the sixth drain is coupled to the voltage power node.

17. The wireless communication apparatus of claim 14, wherein a second VGA unit of the plurality of VGA units comprises:
a first transistor comprising a first gate, a first source, and a first drain, wherein the first gate is coupled to a third control input, and wherein the first drain is coupled to a first terminal of an output;
a second transistor comprising a second gate, a second source, and a second drain, wherein the second gate is coupled to the third control input, and wherein the second drain is coupled to a second terminal of the output;
a third transistor comprising a third gate, a third source, and a third drain, wherein the third drain is coupled to the first source, and wherein the third gate is coupled to a first terminal of an input;
a fourth transistor comprising a fourth gate, a fourth source, and a fourth drain, wherein the fourth drain is coupled to the second source, and wherein the fourth gate is coupled to a second terminal of the input;
a fifth transistor comprising a gate, a source, and a drain, wherein the gate is coupled to a fourth control input, wherein the source is coupled to the first source, and wherein the drain is coupled to the second drain; and
a sixth transistor comprising a gate, a source, and a drain, wherein the gate is coupled to the fourth control input, wherein the source is coupled to the second source, and wherein the drain is coupled to the first drain.

18. A radio frequency (RF) variable gain amplifier (VGA) comprising an RFVGA unit in a folded configuration, the RFVGA unit comprising:
a first transistor comprising a first gate, a first source, and a first drain, wherein the first gate is coupled to a control input, wherein the first source is coupled to a first terminal of an output, and wherein the first drain is coupled to a voltage source via a first resistive element;
a second transistor comprising a second gate, a second source, and a second drain, wherein the second gate is coupled to the control input, wherein the second source is coupled to a second terminal of the output and wherein the first second drain is coupled to the voltage source via a second resistive element;
a third transistor comprising a third gate, a third source, and a third drain, wherein the third drain is coupled to the first drain, and wherein the third gate is coupled to a first terminal of an input; and
a fourth transistor comprising a fourth gate, a fourth source, and a fourth drain, wherein the fourth drain is coupled to the second drain, and wherein the fourth gate is coupled to a second terminal of the input.

19. The RFVGA of claim 18, wherein the third source is coupled to a reference voltage, and wherein the fourth source is coupled to the reference voltage.

20. The RFVGA of claim 19, wherein the RFVGA unit further comprises:
a fifth transistor comprising a fifth gate, a fifth source, and a fifth drain, wherein the fifth drain is coupled to the voltage source, the fifth gate is coupled to a second control input, and wherein the fifth source is coupled to the first source of the first transistor and to the first terminal of the output; and
a sixth transistor comprising a sixth gate, a sixth source, and a sixth drain, wherein the sixth drain is coupled to the voltage source, the sixth gate is coupled to the second control input, and wherein the sixth source is coupled to the second source of the second transistor and to the second terminal of the output.
